(19) United States
(12) Patent Application Publication
(10) Pub. No.: US 2024/0282751 A1
(43) Pub. Date: Aug. 22, 2024

(54) SUBSTRATES WITH DOWNSET

(71) Applicant: Micron Technology, Inc., Boise, ID (US)

(72) Inventors: Ling Pan, Singapore (SG); Seng Kim Ye, Singapore (SG); Kelvin Aik Boo Tan, Singapore (SG); Hong Wan Ng, Singapore (SG); See Hiong Leow, Singapore (SG); Chong C. Hui, Singapore (SG)

(21) Appl. No.: 18/440,444

(22) Filed: Feb. 13, 2024

Related U.S. Application Data
(60) Provisional application No. 63/446,676, filed on Feb. 17, 2023.

(51) Int. Cl. H01L 25/065; H01L 23/00; H01L 23/498

(52) U.S. Cl. CPC H01L 25/0657; H01L 23/49816; H01L 23/49838; H01L 24/08; H01L 24/48; H01L 2224/08146; H01L 2224/08225; H01L 2224/48132; H01L 2224/48147; H01L 2225/06506; H01L 2225/0651; H01L 2225/06562; H01L 2924/1434; H01L 2924/15311; H01L 2924/182; H01L 2924/3511

(57) ABSTRACT

A variety of applications can include systems with packaged electronic devices having multiple dies arranged on a substrate with a downset design. A substrate with a downset design can include an upper portion and a lower portion with a downset portion connecting the upper portion to the lower portion. The downset portion can include through vias to provide conductive paths between the lower portion and the upper portion. Dies can be positioned with a region defined by walls of the downset portion with a non-conductive film covering the dies in the region defined by walls of the downset portion. Additional dies can be positioned on the non-conductive film and the upper portion of the substrate. A packaged electronic device having a substrate with a downset design can be implemented to raise the neutral axis of the packaged electronic device to near the top surface of the dies.

### FIELD OF THE DISCLOSURE

This application claims the benefit of priority to U.S. Provisional Application Ser. No. 63/446,676, filed Feb. 17, 2023, which is incorporated herein by reference in its entirety.

### FIELD OF THE DISCLOSURE

Embodiments of the disclosure relate generally to electronic devices and, more specifically, to structures for semiconductor device packages and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Operation and properties of memory devices and other electronic devices can be improved by enhancements to the design of packaging of electronic devices such as, but not limited to, semiconductor device packages for multiple dies.

### BRIEF DESCRIPTION OF THE DRAWINGS

The drawings, which are not necessarily drawn to scale, illustrate generally, by way of example, but not by way of limitation, various embodiments discussed in the present document.

FIG. 1 is a cross-sectional representation of a packaged electronic device having multiple dies.

FIG. 2 is a representation of a composite beam composed of two parallel portions along a horizontal length of the composite beam, according to various embodiments.

FIG. 3 is a cross-sectional view of the composite beam of FIG. 2, according to various embodiments.

FIG. 4 is a cross-sectional representation of an example packaged electronic device having multiple dies with a multiple section substrate, according to various embodiments.

FIG. 5 is a top view of the example packaged electronic device of FIG. 4 along a top of the substrate of the packaged electronic device, according to various embodiments.

FIG. 6 is a cross-sectional representation of another example packaged electronic device having multiple dies with a multiple section substrate, according to various embodiments.

FIG. 7 is a top view of the example packaged electronic device of FIG. 6 along a top of the substrate of the packaged electronic device, according to various embodiments.

FIG. 8 is a block diagram of an example system having one or more example packaged electronic devices, according to various embodiments.

FIG. 9 is a flow diagram of features of an example method of forming a packaged electronic device, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

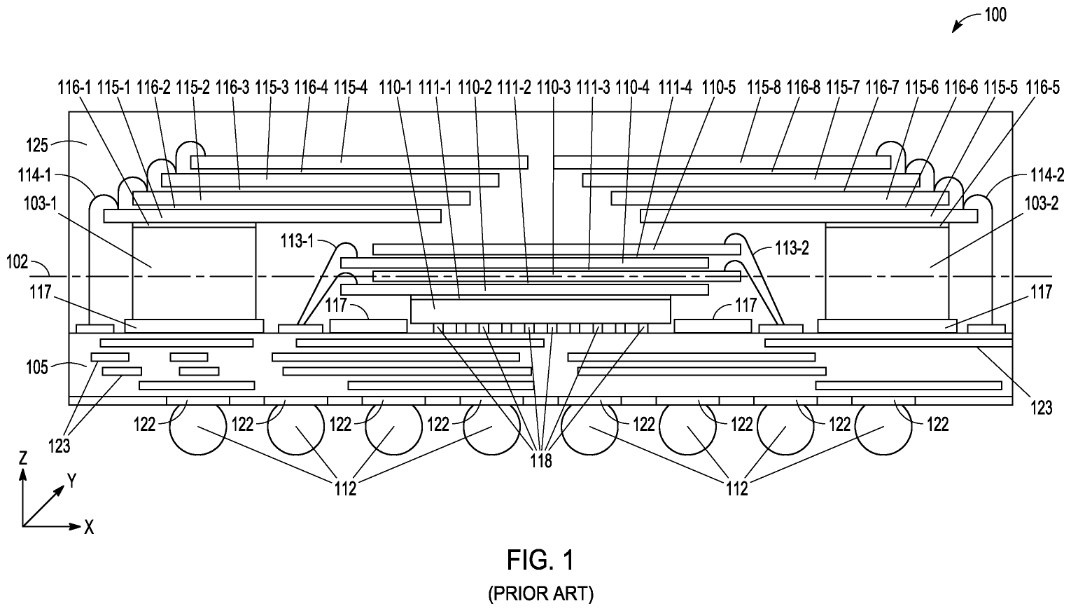

FIG. 1 is a cross-sectional representation of a packaged electronic device 100 having multiple dies supported by a package substrate 105. Dies 110-1, 110-2, 110-3, 110-4, and 110-5 form a first set of dies; dies 115-1, 115-2, 115-3, and 115-4 form a second set of dies; and dies 115-5, 115-6, 115-7, and 115-8 form a third set of dies, where the three sets of dies are arranged for support extending from substrate 105. The sets of dies can be arranged in a level manner; that is, the dies can be arranged parallel to package substrate 105. Die 110-1 is positioned on substrate 105 by contacts 118, with dies 110-2, 110-3, 110-4, and 110-5 positioned on dic 110-1. Contacts 118 can be, but are not limited to, a ball grid array. Die 110-2 can be separated from die 110-1 by a region 111-1. Die 110-3 can be separated from die 110-2 by a region 111-2. Die 110-4 can be separated from die 110-3 by a region 111-3. Die 110-5 can be separated from die 110-4 by a region 111-4. Each of regions 111-1, 111-2, 111-3, and 111-4 can include a backing of the respective die, an adhesive, a die-attach-film (DAF), or a paste, among other materials.

The second set of dies are positioned on and supported by a spacer 103-1, which can be a silicon spacer. Die 115-1 can be separated from a top surface of spacer 103-1 by a region 116-1. Die 115-2 can be separated from die 115-1 by a region 116-2. Die 115-3 can be separated from die 115-2 by a region 116-3. Die 115-4 can be separated from die 115-3 by a region 116-4. Each of regions 116-1, 116-2, 116-3, and 116-4 can include a backing of the respective die, an adhesive, a DAF, or a paste, among other materials.

The third set of dies are positioned on and supported by a spacer 103-2, which can be a silicon spacer. Die 115-5 can be separated from a top surface of spacer 103-2 by a region 116-5. Die 115-6 can be separated from die 115-5 by a region 116-6. Die 115-7 can be separated from die 115-6 by a region 116-7. Die 115-8 can be separated from die 115-7 by a region 116-8. Each of regions 116-5, 116-6, 116-7, and 116-8 can include a backing of the respective die, an adhesive, a DAF, or a paste, among other materials.

In various situations, two or more of dies 110-1, 110-2, 110-3, 110-4, and 110-5 can be the same type of device and can be different from the type of devices implemented in dies 115-1, 115-2, . . . 115-7, and 115-18. In a non-limiting example, dies 110-2, 110-3, 110-4, and 110-5 can be DRAM dies and dies 115-1, 115-2, . . . 115-7, and 115-18 can be NAND memory dies, where die 110-1 can be a controller die. Since different die types are implemented in packaged electronic device 100, it may not be appropriate to arrange all the dies in a common stack. As shown in FIG. 1, spacers 103-1 and 103-2 are implemented to arrange the different types of dies within the dimensions of different sections of packaged electronic device 100. Typically, spacer 103-1 and spacer 103-2 are silicon spacers. However, use of relatively thick silicon spacers can undesirably increase part or production costs.

With spacer 103-1 and spacer 103-2 being silicon spacers different from the materials of the dies, wires, and package substrate 105, there can be an issue of a mismatch of thermal properties within packaged electronic device 100. This thermal issue can be apparent by a mismatch of the coefficient of thermal expansion (CTE) of spacers 103-1 and 103-2 with respect to the other components within packaged electronic device 100. CTE values of different features in packaged electronic device 100 can differ and cause mismatches. Active dies and spacers are typically made of silicon, which is a significantly low CTE material, while the CTE value of other materials in package are much higher than silicon. When such a package goes through high temperature operations or temperature cycling, silicon can shrink or expand to levels different from the other non-silicon material, which can cause stress and strain in coupling of these materials in the package such as packaged electronic device 100. For example, the CTE of a spacer is typically higher than the CTE of mold compound. In some cases, warpage can become out of specification limits due to high shrinkage of mold compound when there is excessive mold compound volume. The CTE mismatch can result in warpage of the dies within packaged electronic device 100, which can reduce the reliability performance of the dies within packaged electronic device 100.

The components of packaged electronic device 100 can be encapsulated with a mold compound 125. This encapsulation includes encapsulation of bond wires to the dies within packaged electronic device 100. Components can be coupled together by DAFs 117. Dies 110-2, 110-3, 110-4, and 110-5 can also be coupled to package substrate 105 by sets of wires 113-1 and 113-2. Dies 115-1, 115-2, 115-3, and 115-4 can be coupled to package substrate 105 by a set of wires 114-1 and dies 115-5, 115-6, 115-7, and 115-8 can be coupled to package substrate 105 by a set of wires 114-2. The sets of wires 114-1 and 114-2 can be substantially longer than the sets of wires 113-1 and 113-2. The longer wires can be susceptible to wire sweep, where wire sweep is a deformation that can occur when bonded wires are not correctly aligned in the horizontal plane. Wire sweep is undesirable, as it can affect electrical performance by changing the mutual inductance of adjacent wires. Wire sweep can occur during forming of mold compound 125. A mismatch associated with spacers 103-1 and 103-2 being relatively large and the dies having varying die size aspect ratios (width to length) within packaged electronic device 100 can result in a relatively large mold compound volume that can lead to wire sweep risk due to one or more long wires of the sets of wires 114-1 and 114-2 extending to the top of dies 115-4 and 115-8, which are at the tops of two die stacks. Such a relatively large mold compound can also lead to excessive mold compound volume, which can be a source of high positive warpage, relative to specifications, of dies such as at 260° C. for current design layouts, for example, as shown in FIG. 1.

Package substrate 105 has contacts 112 coupled to contact pads 122 to allow components of packaged electronic device 100 to communicate, through package substrate 105, with electronic devices or systems exterior to packaged electronic device 100. Conductive paths 123 through substrate 105 are used to facilitate such communication within package substrate 105. Contacts 112 can be implemented by a ball grid array or other arrangements of contacts.

Packaged electronic device 100 having multiple dies supported by package substrate 105 is an illustration of an architecture for a conventional multichip package (MCP) memory. Such a MCP memory can include a controller die, DRAM dies, and NAND dies, where all dies fit within the MCP having silicon spacers adopted for support. Die 110-1 can be a controller die and dies 110-2, 110-3, 110-4, and 110-5 can be DRAM dies. Dies 115-1, 115-2 . . . 115-7, and 115-8 can be NAND dies. Mold compound 125 covers and protects the components of packaged electronic device 100. Mold compound 125 can be flowed to positon above substrate 105, around, between, and among the components of packaged electronic device 100.

The loading of the components within packaged electronic device 100 can lead to a bending stress in packaged electronic device 100 when implementing the package in a system. The directional location of a package at which the bending stress is zero is defined as the neutral axis (NA). For a conventional packaged electronic device, such as packaged electronic device 100, a NA 102 can run through spacers 103-1 and 103-2.

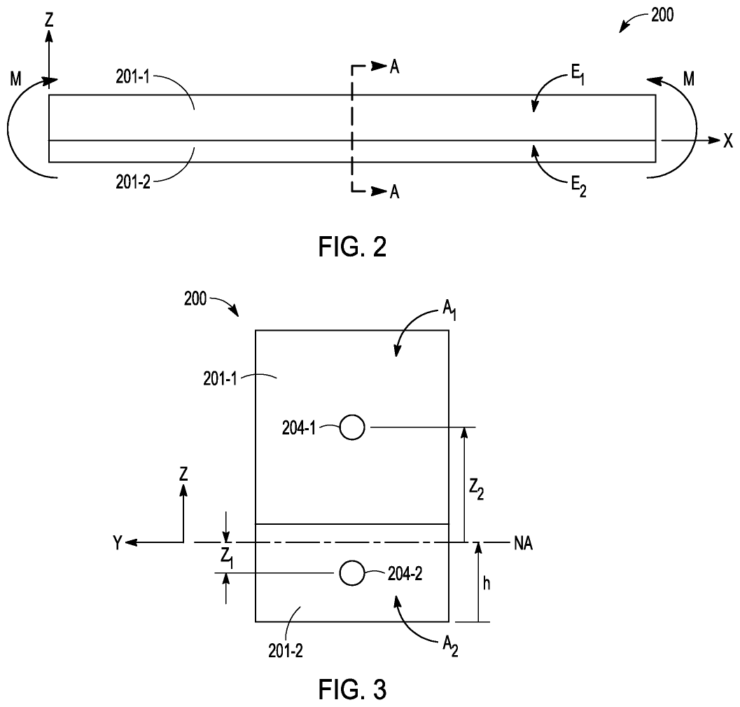

FIG. 2 illustrates a composite beam 200 having a lower beam 201-2 and an upper beam 201-1, where lower beam 201-2 and an upper beam 201-1 have different mechanical properties resulting from different sizes and material compositions. The horizontal interface between lower beam 201-2 and upper beam 201-1 is taken along an x-axis for which there can be a moment M of the area of composite beam about the x-axis. The location of the NA for the composite beam 200 depends on the relative stiffness and size (thickness) of each of the material sections, lower beam 201-2 and an upper beam 201-1. The relative stiffness of a material can be described by Young's modulus, which can also be referred to as the modulus of elasticity, which modulus can be determined as the slope of a stress and strain relationship (ratio of stress to strain corresponding to the strain). In the composite structure, upper beam 201-1 has a Young's modulus of elasticity E₁ and lower beam 201-2 has a Young's modulus of elasticity E₂.

FIG. 3 is a cross-sectional view of the composite beam 200 of FIG. 2 along direction a-a. Upper beam 201-1 has an area A₁ with a center 204-1 and lower beam 201-2 has an area A₂ with a center 204-2. With NA taken along the y-axis, NA of composite beam 200 is taken to be at a height h from the bottom surface of A₂, at a distance of z₁ from center 204-2, and at a distance of 22 from center 204-1. The distances h, z₁, and z₂ and Young's moduli E₁ and E₂ are related to NA by the relationship

$${E}_{1} ( {z}_{1} {A}_{1} ) + {E}_{2} ( {z}_{2} {A}_{2} ) = 0.$$

With A₁=A₂, NA will be closer to the beam having higher stiffness. A substrate with attached dies can be considered as a simple composite beam having a die beam and a substrate beam. Typically, Young's modulus of a die beam is significantly higher than substrate beam.

In analyzing an electronic device package, a model of a composite beam having a die beam and a substrate beam can be implemented. The die beam can include multiple dies, DAFs, and an epoxy mold compound (EMC) covering the multiple dies. The substrate beam can include the substrate and components on and within the substrate structure to support the die beam. It has been determined that higher package (mold) strain, which provides better package strength, is observed when the NA is nearer to a top die surface, that is, when the difference between the distance from the bottom of the substrate to the top die surface and the distance from the bottom of the substrate to the NA is a relative minimum.

In various embodiments, substrates to support multiple dies are structured to provide a packaged electronic device with limited strain. Such substrates can be structured as an upper substrate connected to a lower substrate by a downset substrate, where the downset substrate includes through-vias between the upper substrate and the lower substrate. A substrate with a downset can be realized by a substrate structured in a U-shape pattern with an upper portion, a lower portion, and a connecting portion. The U-shape can have an approximate ninety degree angle from the lower to the upper portion. Other angles between the upper portion and the lower portion can be implemented.

Dies can be positioned with a region defined by walls of the downset portion with a non-conductive film (NCF) covering the dies in the region defined by walls of the downset portion. The NCF can cover walls of the downset, between which walls the dies are positioned. Additional dies can be positioned on the non-conductive film and the upper portion of the substrate. A substrate with a downset can be realized by an upper substrate, a lower substrate, and a downset substrate connecting the upper substrate to the lower substrate. The substrate with a downset shape can have an appropriate ninety degree angle from a lower substrate to an upper substrate. Other angles between the lower substrate and the upper substrate can be implemented.

Dies can be positioned with a region defined by walls of the downset substrate with a NCF covering the dies in the region defined by walls of the downset substrate. The NCF can cover walls of the downset, between which walls the dies are positioned. Additional dies can be positioned on the non-conductive film and the upper portion of the substrate.

The connecting portion and the downset substrate can include through vias between upper substrate to the lower substrate. The architecture for this substrate with a downset design can eliminate use of silicon spacers to support dies on the substrate, where a NCF can be applied over the downset. The NCF can provide strong support to top dies after a curing procedure performed for the NCF. The substrate with downset allows for the construction of a substrate with die locations within the substrate modeled as part of a substrate beam and die locations on and supported by a NCF modeled as a die beam, such that the NA can be located at a more advantageous position for the packaged electronic device using the substrate. A substrate with a downset design can make the NA shift upward towards the top of the dies, which benefits overall package strength.

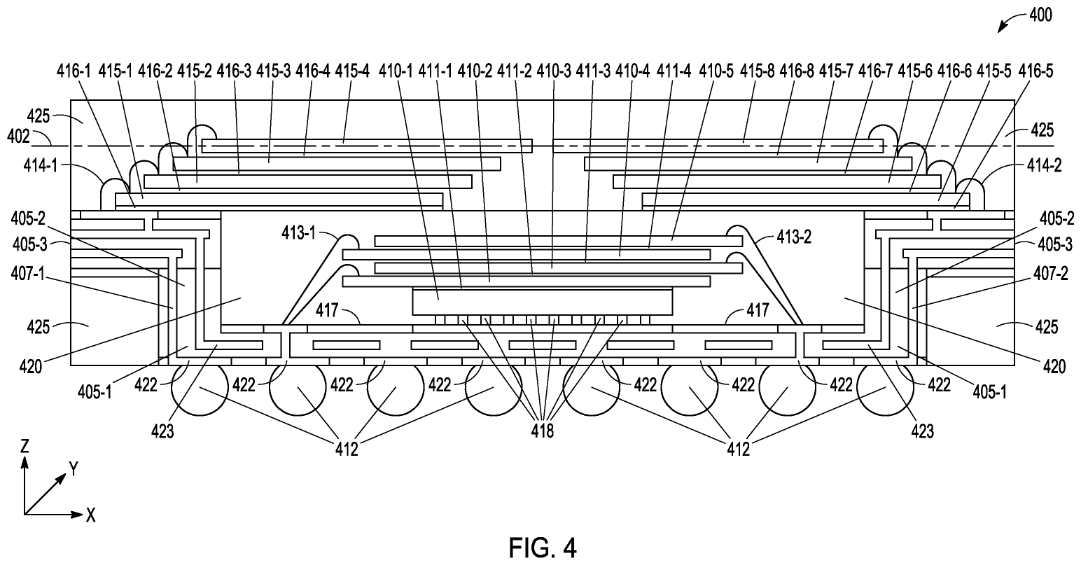

FIG. 4 is a cross-sectional representation of an embodiment of an example packaged electronic device 400 having multiple dies. Dies 410-1, 410-2, 410-3, 410-4, and 410-5 form a first set of dies; dies 415-1, 415-2, 415-3, and 415-4 form a second set of dies; and dies 415-5, 415-6, 415-7, and 415-8 form a third set of dies. The sets of dies can be arranged in a level manner; that is, the dies can be arranged parallel to a substrate for packaged electronic device 400. The substrate of packaged electronic device 400 can include an upper substrate 405-3, a lower substrate 405-1, and a downset substrate 405-2 connecting upper substrate 405-3 to lower substrate 405-1. Upper substrate 405-3, lower substrate 405-1, and downset substrate 405-2 can be implemented as a single substrate. Downset substrate 405-2 can include vias 407-1 and 407-2 to provide conductive paths between lower substrate 405-1 and upper substrate 405-3. Though five dies are shown in the first set, the first set can have more or fewer than five dies. Though four dies are shown in the second set, the second set can have more or fewer than four dies. Though four dies are shown in the third set, the third set can have more or fewer than four dies. The sets of dies can be supported by a substrate structured having multiple sections. The number of dies in each set can depend on the dimensions and material of the substrate with downset formed by upper substrate 405-3, lower substrate 405-1, and downset substrate 405-2.

The first set of dies 410-1, 410-2, 410-3, 410-4, and 410-5 are supported by lower substrate 405-1. Die 410-1 is positioned on lower substrate 405-1 by contacts 418, with dies 410-2, 410-3, 410-4, and 410-5 positioned on die 410-1. Contacts 418 can be, but are not limited to, a ball grid array. Die 410-2 can be separated from die 410-1 by a region 411-1. Die 410-3 can be separated from die 410-2 by a region 411-2. Die 410-4 can be separated from die 410-3 by a region 411-3. Die 410-5 can be separated from die 410-4 by a region 411-4. Each of regions 411-1, 411-2, 411-3, and 411-4 can include a backing of the respective die, an adhesive, a DAF, or a paste, among other materials.

The second set of dies 415-1, 415-2, 415-3, and 415-4 are supported by a portion of upper substrate 405-3. Die 415-1 can be separated from a top surface of the portion of upper substrate 405-3 by a region 416-1. Die 415-2 can be separated from die 415-1 by a region 416-2. Die 415-3 can be separated from die 415-2 by a region 416-3. Die 415-4 can be separated from die 415-3 by a region 416-4. Each of regions 416-1, 416-2, 416-3, and 416-4 can include a backing of the respective die, an adhesive, a DAF, or a paste, among other materials.

The third set of dies 415-5, 415-6, 415-7, and 415-8 are supported by another portion of upper substrate 405-3. Die 415-5 can be separated from a top surface of the other portion of upper substrate by a region 416-5. Die 415-6 can be separated from die 415-5 by a region 416-6. Die 415-7 can be separated from die 415-6 by a region 416-7. Die 415-8 can be separated from die 415-7 by a region 416-8. Each of regions 416-5, 416-6, 416-7, and 416-8 can include a backing of the respective die, an adhesive, a DAF, or a paste, among other materials.

A NCF 420 is located above lower substrate 405-1 and adjacent downset substrate 405-2. NCF 420 be positioned to contact and cover downset substrate 405-2 while covering dies of the first set. NCF 420 covers the first set of dies positioned on lower substrate 405-1 and provides additional support for the second set of dies and the third set of dies that are also supported by upper substrate 405-3. Lower substrate 405-1, with the first set of dies positioned on lower substrate 405-1 covered by NCF 420 and located within the walls of downset substrate 405-2, can be viewed as a lower beam of a two-beam composite beam. The first set of dies and a mold compound 425 covering the first set of dies can form the second beam of the two-beam composite beam. Various materials can be used for the substrates including, but not limited to, a halogen-free bismaleimide triazine resin material or a metal-clad laminate with metal cladding of the metal-clad laminate patterned with conductive routing.

With the substrate with downset design provided by upper substrate 405-3, lower substrate 405-1, and downset substrate 405-2, selecting the number of dies to include along material and sizing of NCF 420, lower substrate 405-1, upper substrate 405-3, and downset substrate 405-1 can place a NA 402 near the top surface of die 415-4 or 415-8. With NA 402 near the top surface of the dies on upper substrate 405-3, packaged electronic device 400 can meet or surpass specifications for package bending performance using a 3-point bending test and a 4-point bending test. In addition to selecting size, positioning, and material of NCF 420 to adjust the position of NA 402, the material of NCF 420 can be selected according to the material's ability to support dies. A wide range of non-conducting materials can be selected for NCF 420. For example, a mold compound material can be used for NCF 420, where NCF 420 is different from mold compound 425. NCF 420 can be formed by a pick and place process, while mold compound 425 is part of an encapsulating process with mold flow. If a mold compound is used as NCF 420, the fabrication would include forming the mold compound in two processes. In various embodiments, material of NCF 420 is different from material of mold compound 425.

In various situations, two or more of dies 410-1, 410-2, 410-3, 410-4, and 410-5 can be the same type of device die and can be different from the type of device dies implemented in dies 415-4, 415-2, . . . 415-17, and 415-18. In a non-limiting example, dies 410-2, 410-3, 410-4, and 410-5 can be DRAM dies and dies 415-1, 415-2, . . . 415-17, and 415-18 can be NAND memory dies, where die 410-1 can be a controller die. Since different die types are implemented in packaged electronic device 400, it may not be appropriate to arrange all the dies in a common stack. As shown in FIG. 4, the substrate with downset design is implemented to arrange the different types of dies within the dimensions of different sections of packaged electronic device 400.

The components of packaged electronic device 400 are encapsulated with a mold compound 425. This encapsulation includes encapsulation of bond wires to the dies within packaged electronic device 400. Components can be coupled together by die-attach-films (DAFs) 417. Dies 410-2, 410-3, 410-4, and 410-5 can also be coupled to contact pads 422 on lower substrate 405-1 by sets of wires 413-1 and 413-2. Dies 415-1, 415-2, 415-3, and 415-4 can be coupled to contact pads 422 on upper substrate 405-3 by a set of wires 414-1 and dies 415-5, 415-6, 415-7, and 415-8 can be coupled to contact pads 422 on upper substrate 405-3 by a set of wires 414-2. The sets of wires 414-1 and 414-2 can have a length comparable to the sets of wires 413-1 and 413-2 based on the substrate with downset design shown in FIG. 4.

Package substrate 405-1 has contacts 412 coupled to contact pads 422 to allow components of packaged electronic device 400 to communicate, through package substrate including lower substrate 405-1, downset substrate 405-2, and upper substrate 405-3, with electronic devices or systems exterior to packaged electronic device 400. Conductive paths 423 and vias 407-1 and 407-2 through lower substrate 405-1, upper substrate 405-3, and downset substrate 405-2 can be used to facilitate such communication within packaged electronic device 400. Contacts 412 can be implemented by a ball grid array or other arrangements of contacts.

As can be seen in comparing FIG. 4 with FIG. 1, the package substrate of FIG. 4 defined by lower substrate 405-1, downset substrate 405-2, and upper substrate 405-3 can provide additional characteristics not provided by package substrate 105 of FIG. 1. The package substrate with downset design of FIG. 4 can eliminate use of a costly and relatively thick silicon spacers (thick relative to the dies housed in packaged electronic devices). Such elimination can reduce the number of components in packaged electronic device 400. A package substrate with downset design, such as that of FIG. 4, can enhance reliability performance by reducing CTE mismatch within packaged electronic device 400. For example, the package substrate with downset design (upper substrate 405-3, downset substrate 405-2, and lower substrate 405-1) can reduce mold compound volume by removing the use of spacers, which can help reduce shrinkage differences to balance warpage behavior when packaged electronic device 400 is in a relatively high temperature range. As seen in FIG. 4, the package substrate with downset design can allow for a shorter wire length that can save cost as well as provide shorter signal path. The wires can be, but are not limited to, gold wires. The package substrate with downset design can also reduce wire sweep risk due to long wires on the die stack extending to the top region of packaged electronic device 400.

With FIG. 4 being a cross-sectional view, other vias and landing pads to these vias are coupled to various ones of the contacts 412 providing communication paths to other sections of packaged electronic device 400. These vias, pads, and contacts can be designed in number and location based on electronic dies to be positioned on the substrate with downset design. The contacts to mate with electrical communication paths exterior to packaged electronic device 400 can be formed to meet designs associated with specifications for application of the electronic dies to be packaged on the substrate with downset design for packaged electronic device 400.

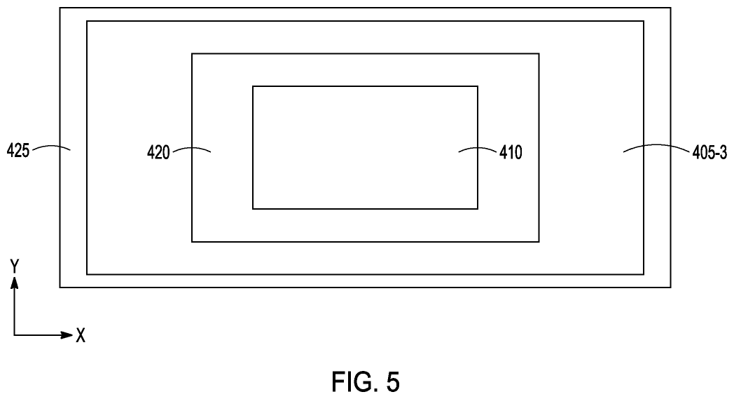

FIG. 5 is a top view of the example packaged electronic device 400 of FIG. 4 along an upper substrate 405-3 of the packaged electronic device 400. Upper substrate 405-3 is a continuous structure having an opening in which NCF 420 is disposed. FIG. 5 shows NCF 420 around the first set of dies 410-1 . . . 410-5, where a top surface 410 of the first set is indicated. The continuous structure of upper substrate 405-3 can include conductive paths coupled to the one or more vias 407-1 and 407-2. About the upper substrate 405-3 is the mold compound 425.

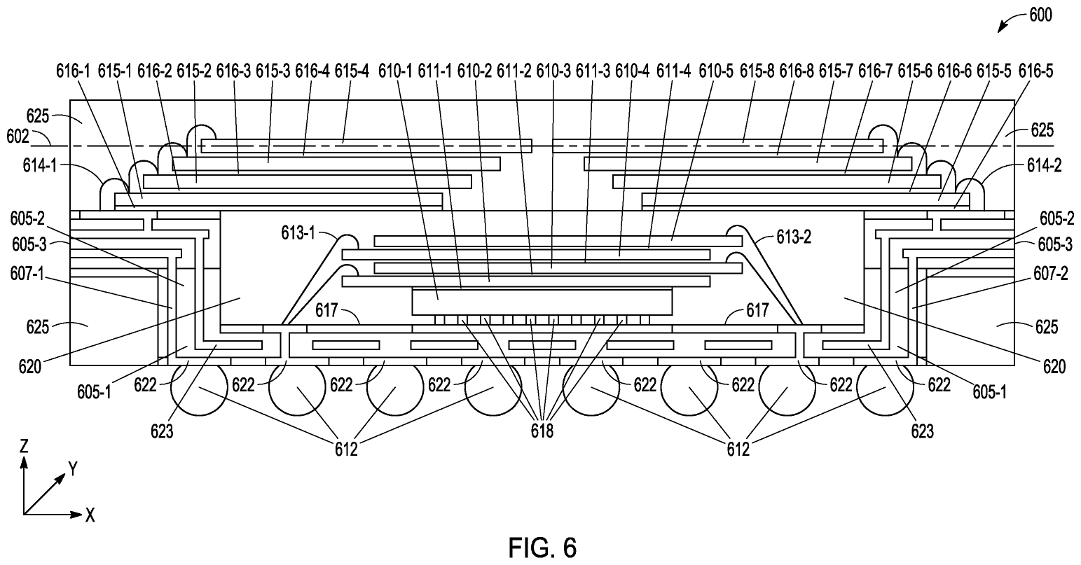

FIG. 6 is a cross-sectional representation of an embodiment of an example packaged electronic device 600 having multiple dies. The cross-section of FIG. 6 is similar to the cross-section of FIG. 4, where packaged electronic device 600 can differ from packaged electronic device 400 by the arrangement in the y-direction of a substrate with downset for the two packaged electronic devices. Dies 610-1, 610-2, 610-3, 610-4, and 610-5 form a first set of dies; dies 615-1, 615-2, 615-3, and 615-4 form a second set of dies; and dies 615-5, 615-6, 615-7, and 615-8 form a third set of dies. The sets of dies can be arranged in a level manner; that is, the dies can be arranged parallel to a substrate for packaged electronic device 600. The substrate of packaged electronic device 600 can include an upper substrate 605-3, a lower substrate 605-1, and a downset substrate 605-2 connecting upper substrate 605-3 to lower substrate 605-1. Upper substrate 605-3, lower substrate 605-1, and downset substrate 605-2 can be implemented as a single substrate. Downset substrate 605-2 can include vias 607-1 and 607-2 to provide conductive paths between lower substrate 605-1 and upper substrate 605-3. Though five dies are shown in the first set, the first set can have more or fewer than five dies. Though four dies are shown in the second set, the second set can have more or fewer than four dies. Though four dies are shown in the third set, the third set can have more or fewer than four dies. The sets of dies can be supported by a substrate structured with multiple sections. The number of dies in each set can depend on the dimensions and material of the substrate with downset formed by upper substrate 605-3, lower substrate 605-1, and downset substrate 605-2.

The first set of dies 610-1, 610-2, 610-3, 610-4, and 610-5 are supported by lower substrate 605-1. Die 610-1 is positioned on lower substrate 605-1 by contacts 618, with dies 610-2, 610-3, 610-4, and 610-5 positioned on die 610-1. Contacts 618 can be, but are not limited to, a ball grid array. Die 610-2 can be separated from die 610-1 by a region 611-1. Die 610-3 can be separated from die 610-2 by a region 611-2. Die 610-4 can be separated from die 610-3 by a region 611-3. Die 610-5 can be separated from die 610-4 by a region 611-4. Each of regions 611-1, 611-2, 611-3, and 611-4 can include a backing of the respective die, an adhesive, or a paste, among other materials.

The second set of dies 615-1, 615-2, 615-3, and 615-4 are supported by a portion of upper substrate 605-3. Die 615-1 can be separated from a top surface of the portion of upper substrate 605-3 by a region 616-1. Die 615-2 can be separated from die 615-1 by a region 616-2. Die 615-3 can be separated from die 615-2 by a region 616-3. Die 615-4 can be separated from die 615-3 by a region 616-4. Each of regions 616-1, 616-2, 616-3, and 616-4 can include a backing of the respective die, an adhesive, a DAF, or a paste, among other materials.

The third set of dies 615-5, 615-6, 615-7, and 615-8 are supported by another portion of upper substrate 605-3. Die 615-5 can be separated from a top surface of the other portion of upper substrate by a region 616-5. Die 615-6 can be separated from die 615-5 by a region 616-6. Die 615-7 can be separated from die 615-6 by a region 616-7. Die 615-8 can be separated from die 615-7 by a region 616-8. Each of regions 616-5, 616-6, 616-7, and 616-8 can include a backing of the respective die, an adhesive, a DAF, or a paste, among other materials.

A NCF 620 is located above lower substrate 605-1 and adjacent downset substrate 605-2. NCF 620 covers the first set of dies positioned on lower substrate 605-1 and provides additional support for the second set of dies and the third set of dies that are also supported by upper substrate 605-3. Lower substrate 605-1 with the first set of dies positioned on lower substrate 605-1 covered by NCF 620 and located within the walls of downset substrate 605-2, can be viewed as a lower beam of a two-beam composite beam. The first set of dies and a mold compound 625 covering the first set of dies can form the second beam of the two-beam composite beam. Various materials can be used for the substrates including, but not limited to, a halogen-free bismaleimide triazine resin material or a metal-clad laminate with metal cladding of the metal-clad laminate patterned with conductive routing.

With the substrate with downset design provided by upper substrate 605-3, lower substrate 605-1, and downset substrate 605-2, selecting material for and sizing NCF 620, lower substrate 605-1, upper substrate 605-3, and downset substrate 605-1 can place a NA 602 near the top surface of die 615-4 or 615-8. With NA 602 near the top surface of the dies on upper substrate 605-3, packaged electronic device 600 can meet or surpass specifications for package bending performance using a 3-point bending test and a 4-point bending test. In addition to selecting size, positioning, and material of NCF 420 to adjust the position of NA 602, the material of NCF 620 can be selected according to the material's ability to support dies. A wide range of non-conducting materials can be selected for NCF 620. For example, a mold compound material can be used for NCF 620, where NCF 620 is different from mold compound 625. NCF 620 can be formed by a pick and place process, while mold compound 625 is part of an encapsulating process with mold flow. If a mold compound is used as NCF 620, the fabrication would include forming the mold compound in two processes. In various embodiments, material of NCF 620 is different from material of mold compound 625.

In various situations, two or more of dies 610-1, 610-2, 610-3, 610-4, and 610-5 can be the same type of device die and can be different from the type of device dies implemented in dies 615-4, 615-2, . . . 615-17, and 615-18. In a non-limiting example, dies 610-2, 610-3, 610-4, and 610-5 can be DRAM dies and dies 615-1, 615-2, . . . 615-17, and 615-18 can be NAND memory dies, where die 610-1 can be a controller die. Since different die types are implemented in packaged electronic device 600, it may not be appropriate to arrange all the dies in a common stack. As shown in FIG. 6, the substrate with downset design can be implemented to arrange the different types of dies within the dimensions of different sections of packaged electronic device 600.

The components of packaged electronic device 600 are encapsulated with a mold compound 625. This encapsulation includes encapsulation of bond wires to the dies within packaged electronic device 600. Components can be coupled together by DAFs 617. Dies 610-2, 610-3, 610-4, and 610-5 can also be coupled to lower substrate 605-1 by sets of wires 613-1 and 613-2. Dies 615-1, 615-2, 615-3, and 615-4 can be coupled to upper substrate 605-3 by a set of wires 614-1 and dies 615-5, 615-6, 615-7, and 615-8 can be coupled to upper substrate 605-3 by a set of wires 614-2. The sets of wires 614-1 and 614-2 can have a length comparable to the sets of wires 613-1 and 613-2 based on the substrate with downset design shown in FIG. 6.

Package substrate 605-1 has contacts 612 coupled to contact pads 622 to allow components of packaged electronic device 600 to communicate, through package substrate including lower substrate 605-1, downset substrate 605-2, and upper substrate 605-3, with electronic devices or systems exterior to packaged electronic device 600. Conductive paths 623 and vias 607-1 and 607-2 through lower substrate 605-1, upper substrate 605-3, and downset substrate 605-2 can be used to facilitate such communication within packaged electronic device 600. Contacts 612 can be implemented by a ball grid array or other arrangements of contacts.

As can be seen in comparing FIG. 6 with FIG. 1, package substrate of FIG. 6 defined by lower substrate 605-1, downset substrate 605-2, and upper substrate 605-3 can provide additional characteristics not provided by package substrate 105 of FIG. 1. The package substrate with downset design of FIG. 6 can eliminate use of a costly and relatively thick silicon spacers (thick relative to the dies housed in packaged electronic devices). Such elimination can reduce the number of components in packaged electronic device 600. A package substrate with downset design, such as that of FIG. 6, can enhance reliability performance by reducing CTE mismatch within packaged electronic device 600. For example, the package substrate with downset design (upper substrate 605-3, downset substrate 605-2, and lower substrate 605-1) can reduce mold compound volume by removing the use of spacers, which can help reduce shrinkage differences to balance warpage behavior when packaged electronic device 600 is in a relatively high temperature range. As seen in FIG. 6, the package substrate with downset design can allow for shorter wire length that can save cost as well as provide shorter signal path. The wires can be, but are not limited to, gold wires. The package substrate with downset design can also reduce wire sweep risk due to long wires on the die stack extending to the top region of packaged electronic device 600.

With FIG. 6 being a cross-sectional view, other vias and landing pads to these vias are coupled to various ones of the contacts 612 providing communication paths to other sections of packaged electronic device 600. These vias, pads, and contacts can be designed in number and location based on electronic dies to be positioned on the substrate with downset design. The contacts to mate with electrical communication paths exterior to packaged electronic device 600 can be formed to meet designs associated with specifications for application of the electronic dies to be packaged on the substrate with downset design for packaged electronic device 600.

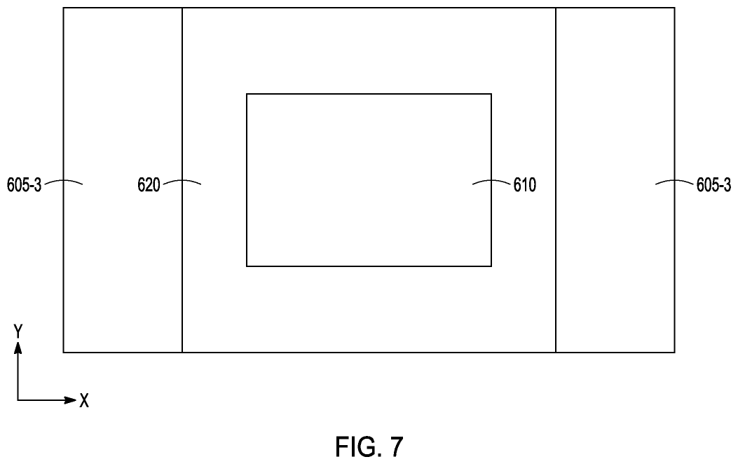

FIG. 7 is a top view of the example packaged electronic device 600 of FIG. 6 along an upper substrate 605-3 of the packaged electronic device 600. Upper substrate 605-3 is non-continuous having a first substantially continuous portion and a second substantially continuous portion. The first portion can include a first set of conductive paths coupled to vias 607-1 of FIG. 6 and the second portion can include a second set of conductive paths coupled to vias 607-2 of FIG. 6. Upper substrate 605-3 has an opening between the first and the second portion in which NCF 620 is disposed. FIG. 7 shows NCF 620 around the first set of dies 610-1 . . . 610-5, where a top surface 610 of the first set is indicated. Similar to FIG. 5, mold compound 625 of FIG. 6 (not shown in FIG. 7) can be disposed about upper substrate 605-3.

Packaged electronic devices having a substrate with downset design, as taught herein, can be manufacturable with various processes. The substrate with downset design can be a single substrate formed with an upper portion, a downset portion, and a lower portion. The downset portion can include through vias providing conductive paths between the lower portion and the upper portion. The substrate with downset design can be formed as an upper substrate connected to a lower substrate by a downset substrate. The downset substrate can include through vias providing conductive paths between the lower substrate and the upper substrate. Such substrates with downset design allow for a set of multiple dies within the downset portion or within the region formed by downset substrates. NCF within the downset provides support for additional dies located on the upper portion or upper substrate. Such package substrates with downset design can provide enhanced package bending performance in 3-point bending tests and 4-point bending tests and improve reliability performance. Such package substrates with downset design can eliminate use of costly thick silicon spacers in electronic device packaging. Such package substrates with downset design can provide shorter gold wire length to save cost as well as shorter signal path and reduce wire sweep risk by avoiding long wires extending to the top of a die stack. Packaged electronic devices using such package substrates with a downset design are not limited to memory devices. Such package substrates can be used in other packaged electronic devices having multiple semiconductor dies.

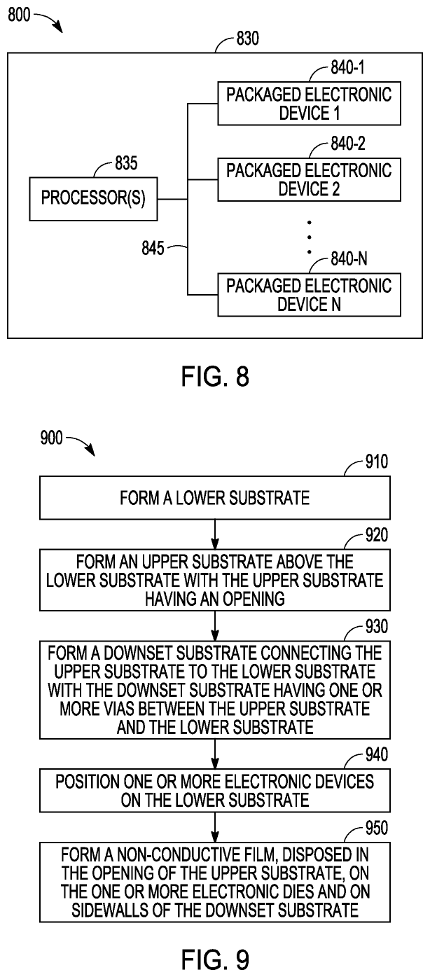

FIG. 8 is a block diagram of an embodiment of an example system 800 having one or more packaged electronic devices 840-1, 840-2 . . . 840-N. One or more of packaged electronic devices 840-1, 840-2 . . . 840-N can include a package substrate having a downset design, as taught herein. Packaged electronic devices 840-1, 840-2 . . . 840-N can operate in conjunction with one or more processors 835. Such operation can be facilitated using routing circuitry 845. One or more of the packaged electronic devices 840-1, 840-2 . . . 840-N can be memory devices.

One or more of the packaged electronic devices 840-1, 840-2 . . . 840-N can include semiconductor dies different from memory dies or memory controllers that perform functions designed to operate according to system specifications for which packaged electronic devices 840-1, 840-2 . . . 840-N are included in the given system. The one or more processors 835, packaged electronic devices 840-1, 840-2 . . . 840-N, and routing circuitry 845 can be implemented on a platform 830. Platform 830 can be, but is not limited to, a printed circuit board or a computer motherboard. Though routing circuitry 845 is shown as individual lines, routing circuitry 845 can be implemented as sets of patterned electrically conductive traces on platform 830. Routing circuitry 845 can be implemented as sets of bundled routing wires.

FIG. 9 is a flow diagram of features of an embodiment of an example method 900 of forming a packaged electronic device. At 910, a lower substrate is formed. At 920, an upper substrate is formed above the lower substrate with the upper substrate having an opening. At 930, a downset substrate is formed connecting the upper substrate to the lower substrate, with the downset substrate having one or more vias between the upper substrate and the lower substrate. The upper substrate, downset substrate, and lower substrate can be formed as a single substrate in which an open region is generated to form the downset substrate in which open region dies can be positioned. At 940, one or more electronic devices are positioned on the lower substrate. At 950, a non-conductive film is formed, disposed in the opening of the upper substrate, on the one or more electronic dies and on sidewalls of the downset substrate.

Variations of method 900 or methods similar to method 900 can include a number of different embodiments that may be combined depending on the application of such methods and/or the architecture of systems including an electronic device for which such methods are implemented. Such methods can include positioning one or more additional electronic dies above and supported by the non-conductive film. A mold compound can be formed covering the one or more additional electronic dies, the upper substrate, the downset substrate, and the lower substrate.

Variations of method 900 or methods similar to method 900 can include forming the packaged electronic device having a neutral axis at about a top of electronic dies above a top surface of the upper substrate. Forming the packaged electronic device having the neutral axis positioned at about the top of electronic dies above the top surface of the upper substrate can include, with respect to quantities and sizes of the one or more electronic devices, selecting material of the non-conductive film, the lower substrate, the upper substrate, and the downset substrate and sizing the non-conductive film, the lower substrate, the upper substrate, and the downset substrate with respect to quantities and sizes of the one or more electronic devices.

Variations of method 900 or methods similar to method 900 can include curing the non-conductive film after forming the non-conductive film. Variations can include forming the upper substrate as a continuous structure around the opening, with the continuous structure having conductive paths coupled to the one or more vias. Variations can include forming the upper substrate as two separate continuous structures providing the opening, with each of the two continuous structures having conductive paths coupled to the one or more vias.

In various embodiments, an electronic device can comprise one or more electronic dies, a lower substrate, an upper substrate, and a downset substrate. The lower substrate is constructed on which the one or more electronic dies can be positioned. The upper substrate is positioned above the lower substrate, where the upper substrate has an opening above the one or more electronic dies. The downset substrate connects the upper substrate to the lower substrate, where the downset substrate has one or more vias between the upper substrate and the lower substrate. A non-conductive film can be disposed in the opening of the upper substrate, on the one or more electronic dies and on sidewalls of the downset substrate.

Variations of such an electronic device and its features, as taught herein, can include a number of different embodiments and features that can be combined depending on the application of such electronic devices, the format of such electronic devices, and/or the architecture in which such electronic devices are implemented. Variations of such an electronic device can include one or more additional electronic dies being positioned above and supported by the non-conductive film. The electronic device can be a packaged electronic device having a neutral axis positioned at about a top of the electronic dies on the upper substrate. The electronic device can include package electrical contacts coupled to the lower substrate, where one or more of the package electrical contacts can be configured to provide signals, via the one or more vias, between the one or more additional electronic dies and one or more devices external to the electronic device. The electronic device can include package electrical contacts coupled to the lower substrate, where one or more of the package electrical contacts can be configured to provide signals between the one or more electronic dies and one or more devices external to the electronic device.

Variations of such an electronic device and its features can include the upper substrate being a continuous structure around the opening, where the continuous structure can include conductive paths coupled to the one or more vias. Variations of such an electronic device can include the opening of the upper substrate separating a first portion of the upper substrate from a second portion of the upper substrate such that the upper substrate is non-continuous between the first portion and the second portion. The first portion can include a first set of conductive paths coupled to a first via set of the one or more vias and the second portion can include a second set of conductive paths coupled to a second via set of the one or more vias.

Such an electronic device can include one or more additional electronic dies positioned above and supported by the non-conductive film. A mold compound can be structured to provide a cover to the one or more additional electronic dies, the upper substrate, the downset substrate, and the lower substrate.

In various embodiments, a system can comprise at least one packaged electronic device. The at least one packaged electronic device can include a processing device die and memory device dies coupled to the processing device, with the processing device die and the memory device dies positioned on a substrate. The substrate can include a lower substrate, an upper substrate, and a downset substrate. The processing device die and memory device dies can be positioned on the lower substrate. The upper substrate can be structured above the lower substrate, where the upper substrate has an opening above the memory device dies that are positioned on the lower substrate. The downset substrate connects the upper substrate to the lower substrate, where the downset substrate has one or more vias between the upper substrate and the lower substrate. A non-conductive film can be disposed in the opening of the upper substrate, on the memory device dies and on sidewalls of the downset substrate.

Variations of such a system and its features, as taught herein, can include a number of different embodiments and features that can be combined depending on the application of such systems, the format of such systems, and/or the architecture in which such systems are implemented. Variations of such a system can include the at least one packaged electronic device having a neutral axis at about a top surface of a top additional die on the upper substrate of the at least one packaged electronic device.

Variations of such a system can include one or more additional dies positioned above and supported by the non-conductive film in the at least one packaged electronic device. The memory device dies can include volatile memory devices and the one or more additional dies can include one or more non-volatile memory dies. Variations can include packaging of the at least one packaged electronic device having a mold compound structured to provide a cover to the one or more additional dies, the upper substrate, the downset substrate, and the lower substrate.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., internet-of-things (IoT) devices, etc.), have varying storage needs depending on, among other things, the type of electronic device, use environment, performance expectations, etc. Such electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices. These electronic devices provide examples of structures that can include a substrate with a downset design similar to substrates with a downset design discussed herein.

The following example embodiments of methods, devices, and systems, in accordance with the teachings herein.

An example electronic device 1 can comprise: one or more electronic dies; a lower substrate on which the one or more electronic dies are positioned; an upper substrate above the lower substrate, the upper substrate having an opening above the one or more electronic dies; a downset substrate connecting the upper substrate to the lower substrate, the downset substrate having one or more vias between the upper substrate and the lower substrate; and a non-conductive film disposed in the opening of the upper substrate, on the one or more electronic dies and on sidewalls of the downset substrate.

An example electronic device 2 can include features of example electronic device 1 and can include one or more additional electronic dies being positioned above and supported by the non-conductive film.

An example electronic device 3 can include features of example electronic device 2 and any features of the preceding example electronic devices and can include the electronic device being a packaged electronic device having a neutral axis at a top surface of the one or more additional electronic dies.

An example electronic device 4 can include features of example electronic device 2 and any features of the preceding example electronic devices and can include package electrical contacts coupled to the lower substrate, one or more of the package electrical contacts configured to provide signals, via the one or more vias, between the one or more additional electronic dies and one or more devices external to the electronic device.

An example electronic device 5 can include features of any of the preceding example electronic devices and can include package electrical contacts coupled to the lower substrate, one or more of the package electrical contacts configured to provide signals between the one or more electronic dies and one or more devices external to the electronic device.

An example electronic device 6 can include features of any of the preceding example electronic devices and can include the upper substrate being a continuous structure around the opening, the continuous structure including conductive paths coupled to the one or more vias.

An example electronic device 7 can include features of example electronic device 6 and any of the preceding example electronic devices and can include the opening of the upper substrate separating a first portion of the upper substrate from a second portion of the upper substrate such that the upper substrate is non-continuous between the first portion and the second portion, the first portion including a first set of conductive paths coupled to a first via set of the one or more vias and the second portion including a second set of conductive paths coupled to a second via set of the one or more vias.

An example electronic device 8 can include features of any of the preceding example electronic devices and can include one or more additional electronic dies being positioned above and supported by the non-conductive film; and a mold compound being structured to provide a cover to the one or more additional electronic dies, the upper substrate, the downset substrate, and the lower substrate.

In an example electronic device 9, any of the electronic devices of example electronic devices 1 to 8 may include electronic devices incorporated into an electronic apparatus further comprising a host processor and a communication bus extending between the host processor and the electronic device.

In an example electronic device 10, any of the electronic devices of example electronic devices 1 to 9 may be modified to include any structure presented in another of example electronic device 1 to 9.

In an example electronic device 11, any apparatus associated with the electronic devices of example electronic devices 1 to 10 may further include a machine-readable storage device configured to store instructions as a physical state, wherein the instructions may be used to perform one or more operations of the apparatus.

In an example electronic device 12, any of the electronic devices of example electronic devices 1 to 11 may be formed in accordance with any of the below example methods 1 to 11.

An example system 1 can comprise: at least one packaged electronic device, the at least one packaged electronic device including: a processing device die; memory device dies coupled to the processing device; a lower substrate on which the processing device die and memory device dies are positioned; an upper substrate above the lower substrate, the upper substrate having an opening above the memory device dies; a downset substrate connecting the upper substrate to the lower substrate, the downset substrate having one or more vias between the upper substrate and the lower substrate; and a non-conductive film disposed in the opening of the upper substrate, on the memory device dies and on sidewalls of the downset substrate.

An example system 2 can include features of preceding example system 1 and can include the at least one packaged electronic device having a neutral axis at a top surface of the upper substrate of the at least one packaged electronic device.

An example system 3 can include features of any of the preceding example systems and can include one or more additional dies being positioned above and supported by the non-conductive film in the at least one packaged electronic device.

An example system 4 can include features of example system 3 and any of the preceding example packaged electronic devices and can include the one or more memory device dies including volatile memory devices and the one or more additional dies including one or more non-volatile memory dies.

An example system 5 can include features of example system 4 and any features of the preceding example packaged electronic devices and can include packaging of the at least one packaged electronic device including a mold compound structured to provide a cover to the one or more additional electronic dies, the upper substrate, the downset substrate, and the lower substrate.

In an example system 6, any of the systems of example systems 1 to 5 may include systems incorporated into an electronic apparatus further comprising a host processor and a communication bus extending between the host processor and the systems.

In an example system 7, any of the systems of example systems 1 to 6 may be modified to include any structure presented in another of example system 1 to 6.

In an example system 8, any apparatus associated with the systems of example systems 1 to 7 may further include a machine-readable storage device configured to store instructions as a physical state, wherein the instructions may be used to perform one or more operations of the apparatus.

In an example system 9, any of the systems of example systems 1 to 8 may be formed in accordance with any of the methods of the below example methods 1 to 11.

An example method 1 of forming a packaged electronic device can comprise: forming a lower substrate; forming an upper substrate above the lower substrate with the upper substrate having an opening; forming a downset substrate connecting the upper substrate to the lower substrate, with the downset substrate having one or more vias between the upper substrate and the lower substrate; positioning one or more electronic devices on the lower substrate; and forming a non-conductive film, disposed in the opening of the upper substrate, on the one or more electronic dies and on sidewalls of the downset substrate.

An example method 2 of forming a packaged electronic device can include features of example method 1 of forming a packaged electronic device and can include positioning one or more additional electronic dies above and supported by the non-conductive film.

An example method 3 of forming a packaged electronic device can include features of example method 2 and any of the preceding example methods of forming a packaged electronic device and can include forming a mold compound covering the one or more additional electronic dies, the upper substrate, the downset substrate, and the lower substrate.

An example method 4 of forming a packaged electronic device can include features of example method 2 and any of the preceding example methods of forming a packaged electronic device and can include forming the packaged electronic device having a neutral axis at a top surface of the one or more additional electronic dies.

An example method 5 of forming a packaged electronic device can include features of example method 4 of forming a packaged electronic device and any of the preceding example methods of forming a packaged electronic device and can include forming the packaged electronic device having the neutral axis at the top surface of the upper substrate material to include, with respect to quantities and sizes of the one or more electronic devices, selecting material of the non-conductive film, the lower substrate, the upper substrate, and the downset substrate, and sizing the non-conductive film, the lower substrate, the upper substrate, and the downset substrate.

An example method 6 of forming a packaged electronic device can include features of any of the preceding example methods of forming a packaged electronic device and can include curing the non-conductive film after forming the non-conductive film.

An example method 7 of forming a packaged electronic device can include features of any of the preceding example methods of forming a packaged electronic device and can include forming the upper substrate as a continuous structure around the opening, with the continuous structure having conductive paths coupled to the one or more vias.

In an example method 8 of forming a packaged electronic device, any of the example methods 1 to 7 of forming a packaged electronic device may be performed in forming a packaged electronic device further comprising a host processor and a communication bus extending between the host processor and the packaged electronic device.

In an example method 9 of forming a packaged electronic device, any of the example methods 1 to 8 of forming a packaged electronic device may be modified to include operations set forth in any other of example methods 1 to 8 of forming a packaged electronic device.

In an example method 10 of forming a packaged electronic device, any of the example methods 1 to 9 of forming a packaged electronic device may be implemented at least in part through use of instructions stored as a physical state in one or more machine-readable storage devices.

An example method 11 of forming a packaged electronic device can include features of any of the preceding example methods 1 to 10 and can include performing functions associated with any features of example electronic devices 1 to 12 and systems 1 to 9.

An example machine-readable storage device 1 storing instructions that when executed by one or more processors, cause a machine to perform operations, can comprise instructions to perform functions associated with any features of example electronic device 1 to 12 and example systems 1 to 9 or perform methods associated with any features of example methods 1 to 11.

Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. An electronic device comprising:
one or more electronic dies;
a lower substrate on which the one or more electronic dies are positioned;
an upper substrate above the lower substrate, the upper substrate having an opening above the one or more electronic dies;
a downset substrate connecting the upper substrate to the lower substrate, the downset substrate having one or more vias between the upper substrate and the lower substrate; and
a non-conductive film disposed in the opening of the upper substrate, on the one or more electronic dies and on sidewalls of the downset substrate.

2. The electronic device of claim 1, wherein one or more additional electronic dies are positioned above and supported by the non-conductive film.

3. The electronic device of claim 2, wherein the electronic device is a packaged electronic device having a neutral axis at a top surface of the one or more additional electronic dies.

4. The electronic device of claim 2, wherein the electronic device includes package electrical contacts coupled to the lower substrate, one or more of the package electrical contacts configured to provide signals, via the one or more vias, between the one or more additional electronic dies and one or more devices external to the electronic device.

5. The electronic device of claim 1, wherein the electronic device includes package electrical contacts coupled to the lower substrate, one or more of the package electrical contacts configured to provide signals between the one or more electronic dies and one or more devices external to the electronic device.

6. The electronic device of claim 1, wherein the upper substrate is a continuous structure around the opening, the continuous structure including conductive paths coupled to the one or more vias.

7. The electronic device of claim 1, wherein the opening of the upper substrate separates a first portion of the upper substrate from a second portion of the upper substrate such that the upper substrate is non-continuous between the first portion and the second portion, the first portion including a first set of conductive paths coupled to a first via set of the one or more vias and the second portion including a second set of conductive paths coupled to a second via set of the one or more vias.

8. The electronic device of claim 1, wherein:
one or more additional electronic dies are positioned above and supported by the non-conductive film; and
a mold compound is structured to provide a cover to the one or more additional electronic dies, the upper substrate, the downset substrate, and the lower substrate.

9. A system comprising:
at least one packaged electronic device, the at least one packaged electronic device including:
a processing device die;
memory device dies coupled to the processing device;
a lower substrate on which the processing device die and memory device dies are positioned;
an upper substrate above the lower substrate, the upper substrate having an opening above the memory device dies;
a downset substrate connecting the upper substrate to the lower substrate, the downset substrate having one or more vias between the upper substrate and the lower substrate; and
a non-conductive film disposed in the opening of the upper substrate, on the memory device dies and on sidewalls of the downset substrate.

10. The system of claim 9, wherein the at least one packaged electronic device has a neutral axis at a top surface of the upper substrate of the at least one packaged electronic device.

11. The system of claim 9, wherein one or more additional dies are positioned above and supported by the non-conductive film in the at least one packaged electronic device.

12. The system of claim 11, wherein the memory device dies include volatile memory devices and the one or more additional dies include one or more non-volatile memory dies.

13. The system of claim 11, wherein packaging of the at least one packaged electronic device includes a mold compound structured to provide a cover to the one or more additional dies, the upper substrate, the downset substrate, and the lower substrate.

14. A method of forming a packaged electronic device, the method comprising:
forming a lower substrate;
forming an upper substrate above the lower substrate with the upper substrate having an opening;
forming a downset substrate connecting the upper substrate to the lower substrate, with the downset substrate having one or more vias between the upper substrate and the lower substrate;
positioning one or more electronic devices on the lower substrate; and
forming a non-conductive film, disposed in the opening of the upper substrate, on the one or more electronic dies and on sidewalls of the downset substrate.

15. The method of claim 14, wherein the method includes positioning one or more additional electronic dies above and supported by the non-conductive film.

16. The method of claim 15, wherein the method includes forming a mold compound covering the one or more additional electronic dies, the upper substrate, the downset substrate, and the lower substrate.

17. The method of claim 15, wherein the method includes forming the packaged electronic device having a neutral axis at a top surface of the one or more additional electronic dies.

18. The method of claim 17, wherein forming the packaged electronic device having the neutral axis at the top surface of the upper substrate includes, with respect to quantities and sizes of the one or more electronic devices:
selecting material of the non-conductive film, the lower substrate, the upper substrate, and the downset substrate; and
sizing the non-conductive film, the lower substrate, the upper substrate, and the downset substrate.

19. The method of claim 14, wherein the method includes curing the non-conductive film after forming the non-conductive film.

20. The method of claim 14, wherein the method includes forming the upper substrate as a continuous structure around the opening, with the continuous structure having conductive paths coupled to the one or more vias.
